(19) United States
(12) Patent Application Publication
(10) Pub. No.: US 2024/0249987 A1
(43) Pub. Date: Jul. 25, 2024

(54) SEMICONDUCTOR DEVICE AND METHOD FOR MANUFACTURING SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Shunsuke KAMIYA, Komatsu Ishikawa (JP); Kazuhiro MURAKAMI, Nomi Ishikawa (JP)

(21) Appl. No.: 18/463,819

(22) Filed: Sep. 8, 2023

(30) Foreign Application Priority Data
Jan. 23, 2023 (JP) 2023-008295

(51) Int. Cl. H01L 23/31; H01L 21/56; H01L 21/784; H01L 23/00

(52) U.S. Cl. CPC H01L 23/3135; H01L 21/561; H01L 21/784; H01L 24/29; H01L 24/32; H01L 24/83; H01L 23/291

(57) ABSTRACT

A semiconductor device includes a conductive member, a solder layer, a chip, a coating film, an insulating part, and a sealing resin. The solder layer is located on the conductive member. The chip is located on the solder layer. The coating film is insulative. The coating film is located on the chip. The coating film includes a first covering part. The first covering part covers an outer perimeter edge of an upper surface of the chip. The insulating part is located on the coating film. The sealing resin seals the solder layer, the chip, the coating film, and the insulating part.

### CROSS-REFERENCE TO RELATED APPLICATIONS

This application is based upon and claims the benefit of priority from Japanese Patent Application No. 2023-008295, filed on Jan. 23, 2023; the entire contents of which are incorporated herein by reference.

### FIELD Embodiments described herein relate generally to a semiconductor device and a method for manufacturing a semiconductor device.

### BACKGROUND

Semiconductor devices such as MOSFETs (Metal-Oxide-Semiconductor Field-Effect Transistors) and the like are used in applications such as power conversion, etc. It is desirable to increase the reliability of semiconductor devices.

### BRIEF DESCRIPTION OF THE DRAWINGS

FIG. 1 is a cross-sectional view illustrating a semiconductor device according to a first embodiment;

FIGS. 2A to 2D are cross-sectional views illustrating an example of the method for manufacturing the semiconductor device according to the first embodiment;

FIG. 3 is a cross-sectional view illustrating a semiconductor device according to a second embodiment;

FIGS. 4A to 4D are cross-sectional views illustrating an example of the method for manufacturing the semiconductor device according to the second embodiment;

FIG. 5 is a cross-sectional view illustrating a semiconductor device according to a third embodiment;

FIGS. 6A and 6B are cross-sectional views illustrating an example of the method for manufacturing the semiconductor device according to the third embodiment;

FIG. 7 is a cross-sectional view illustrating a semiconductor device according to a fourth embodiment; and

FIGS. 8A to 8C are cross-sectional views illustrating an example of the method for manufacturing the semiconductor device according to the fourth embodiment.

### DETAILED DESCRIPTION

A semiconductor device according to an embodiment includes a conductive member, a solder layer, a chip, a coating film, an insulating part, and a sealing resin. The solder layer is located on the conductive member. The chip is located on the solder layer. The coating film is insulative. The coating film is located on the chip. The coating film includes a first covering part. The first covering part covers an outer perimeter edge of an upper surface of the chip. The insulating part is located on the coating film. The sealing resin seals the solder layer, the chip, the coating film, and the insulating part.

Exemplary embodiments will now be described with reference to the drawings. The drawings are schematic or conceptual; and the relationships between the thickness and width of portions, the proportional coefficients of sizes among portions, etc., are not necessarily the same as the actual values thereof. Furthermore, the dimensions and proportional coefficients may be illustrated differently among drawings, even for identical portions. Furthermore, in the specification of the application and the drawings, components similar to those described in regard to a drawing thereinabove are marked with like reference numerals; and a detailed description is omitted as appropriate.

For easier understanding of the following description, the arrangements and configurations of the portions are described using an XYZ orthogonal coordinate system. An X-axis, a Y-axis, and a Z-axis are orthogonal to each other. The direction in which the X-axis extends is taken as an “X-direction”; the direction in which the Y-axis extends is taken as a “Y-direction”; and the direction in which the Z-axis extends is taken as a “Z-direction”. Although the direction of the arrow in the Z-direction is taken as up and the opposite direction is taken as down for easier understanding of the description, these directions are independent of the direction of gravity.

### First Embodiment

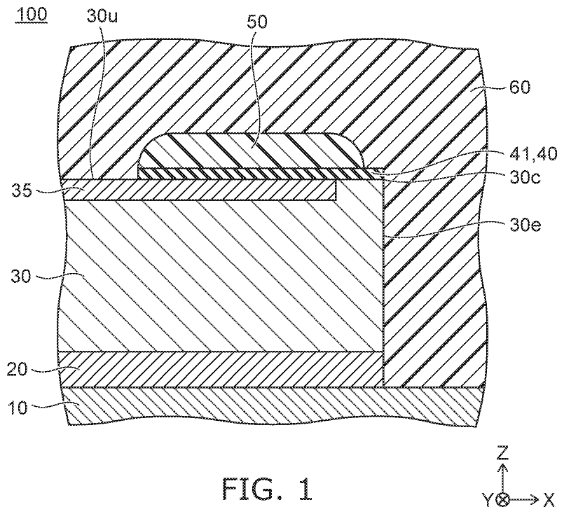

FIG. 1 is a cross-sectional view illustrating a semiconductor device according to a first embodiment.

As illustrated in FIG. 1, the semiconductor device 100 according to the first embodiment includes a conductive member 10, a solder layer 20, a chip 30, a coating film 40, an insulating part 50, and a sealing resin 60.

The conductive member 10 is, for example, a plate made of metal. The conductive member 10 includes, for example, a metal such as copper, iron, etc.

The solder layer 20 is located on the conductive member 10. The solder layer 20 is located between the conductive member 10 and the chip 30 and connects the conductive member 10 and the chip 30. The solder layer 20 includes lead. For example, the solder layer 20 includes lead as a major component. The solder layer 20 mayinclude a metal other than lead.

The chip 30 is located on the solder layer 20. The chip 30 is placed on the conductive member 10 with the solder layer 20 interposed. The chip 30 is, for example, a semiconductor element such as a MOSFET, etc. The thickness (the length in the vertical direction) of the chip 30 is, for example, not more than 100 μm.

The chip 30 includes, for example, a metal part 35. The metal part 35 is located in the upper portion of the chip 30. The metal part 35 is included in an upper surface 30u of the chip 30.

The metal part 35 is, for example, a plate made of metal. The metal part 35 includes, for example, a metal such as copper, etc. A gold film formed of gold plating or the like is at the upper surface 30u of the chip 30. For example, the metal part 35 functions as an electrode. For example, a lower voltage than that of the solder layer 20 is applied to the metal part 35. For example, instead of the metal part 35, the chip 30 mayinclude a part to which a lower voltage than that of the solder layer 20 is applied.

The coating film 40 is located on the chip 30. The coating film 40 is an insulating film. The coating film 40 includes, for example, at least one of silicon nitride, silicon oxide, or silicon oxynitride.

The coating film 40 includes a first covering part 41. The first covering part 41 covers an outer perimeter edge 30c of the upper surface 30u of the chip 30. The first covering part 41 is positioned above the outer perimeter edge 30c. The outer perimeter edge 30c is the outermost portion of the upper surface 30u of the chip 30 when viewed in top-view. The outer perimeter edge 30c is a corner portion between the upper surface 30u of the chip 30 and a side surface 30e of the chip 30. The first covering part 41 covers the outer perimeter edge 30c of the upper surface 30u of the chip 30 over the entire perimeter of the chip 30.

The first covering part 41 maycover portions of the upper surface 30u of the chip 30 other than the outer perimeter edge 30c. For example, the first covering part 41 covers at least a portion of the upper surface of the metal part 35. The first covering part 41 maynot cover a portion of the top of the chip 30. For example, the first covering part 41 maynot cover a portion of the upper surface of the metal part 35.

The insulating part 50 is located on the coating film 40. The insulating part 50 includes, for example, a resin. The insulating part 50 includes, for example, a polyimide resin. The insulating part 50 includes, for example, a non-photosensitive polyimide resin. For example, the insulating part 50 overlaps the metal part 35 in the vertical direction. For example, the insulating part 50 does not overlap the outer perimeter edge 30c of the upper surface 30u of the chip 30 in the vertical direction.

The sealing resin 60 seals the solder layer 20, the chip 30, the coating film 40, and the insulating part 50. The sealing resin 60 covers the top and side of the solder layer 20, the chip 30, the coating film 40, and the insulating part 50. The sealing resin 60 includes, for example, a thermosetting resin such as an epoxy resin, a silicone resin, etc.

Effects of the semiconductor device 100 according to the first embodiment will now be described.

When thermal stress is applied to the semiconductor device, there are cases where a gap occurs between the conductive member, the solder layer, the chip, the coating film, the insulating part, and the sealing resin. If water penetrates the gap, the lead that is included in the solder layer is ionized, and lead ions (Pb²⁺) that are generated move along the gap and reach the upper surface of the chip. Portions of the chip where the surface of the chip is not covered with a coating film expand due to anodic oxidation of the silicon included in the chip. In a conventional semiconductor device, the outer perimeter edge of the upper surface of the chip is not covered with a coating film; therefore, there are cases where the outer perimeter edge of the upper surface of the chip expands, and cracks may occur in the upper surface of the chip. There is a risk that short defects may occur if the lead ions reach the upper surface of the chip when such cracks exist.

In contrast, in the semiconductor device 100 according to the first embodiment, the expansion of the chip 30 can be suppressed because the outer perimeter edge 30c of the upper surface 30u of the chip 30 is covered with the coating film 40 (the first covering part 41). Cracks in the upper surface 30u of the chip 30 can be suppressed thereby, and short defects can be suppressed even when lead ions are generated. Accordingly, the reliability of the semiconductor device can be increased.

The moisture resistance and/or strength can be increased by the coating film 40 including at least one of silicon nitride, silicon oxide, or silicon oxynitride. The moisture resistance can be increased when the coating film 40 includes silicon nitride. The strength can be increased when the coating film 40 includes silicon oxide. The coating film 40 can have a good balance of moisture resistance and strength when the coating film 40 includes silicon oxynitride.

A method for manufacturing the semiconductor device 100 according to the first embodiment will now be described.

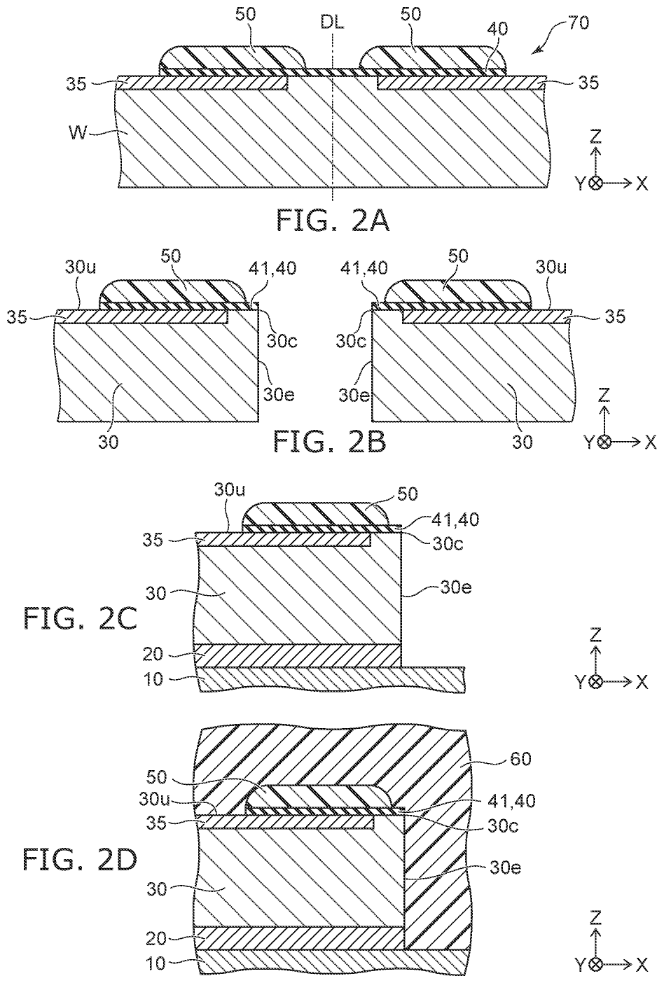

FIGS. 2A to 2D are cross-sectional views illustrating an example of the method for manufacturing the semiconductor device according to the first embodiment.

As illustrated in FIGS. 2A to 2D, the method for manufacturing the semiconductor device 100 according to the first embodiment includes a preparation process, a dicing process, a connection process, and a sealing process.

According to the method for manufacturing the semiconductor device 100 according to the first embodiment, first, the preparation process is performed as illustrated in FIG. 2A. In the preparation process, a stacked body 70 is prepared in which the coating film 40 is formed on a wafer W used to form the chip 30, and the insulating part 50 is formed on the coating film 40. At this time, the coating film 40 is formed to overlap, in the vertical direction, a dicing line DL which is the position at which dicing is performed in the dicing process. For example, the coating film 40 is formed by CVD (Chemical Vapor Deposition) using TEOS (tetraethyl orthosilicate). For example, the insulating part 50 is formed by coating a resin material.

Then, according to the method for manufacturing the semiconductor device 100 according to the first embodiment, the dicing process is performed as illustrated in FIGS. 2A and 2B. In the dicing process, the chip 30 in which the coating film 40 and the insulating part 50 are stacked is obtained by dicing the stacked body 70 at a position at which the coating film 40 is located. In the dicing process, the stacked body 70 is diced along the dicing line DL. The dicing may be performed using a blade or may be performed using a laser.

In the dicing process of a conventional semiconductor device manufacturing method, dicing is performed after removing the coating film at the position overlapping the dicing line DL. That is, in the dicing process of a conventional semiconductor device manufacturing method, dicing is performed at a position at which the coating film is not located. Therefore, in a conventional semiconductor device, the coating film (the first covering part) that covers the outer perimeter edge of the upper surface of the chip is not formed.

In contrast, in the dicing process of the method for manufacturing the semiconductor device 100 according to the first embodiment, dicing is performed at a position at which the coating film 40 is located without removing the coating film 40 at the position overlapping the dicing line DL. The chip 30 in which the coating film 40 (the first covering part 41) covering the outer perimeter edge 30c of the upper surface 30u of the chip 30 is formed can be obtained thereby.

Then, according to the method for manufacturing the semiconductor device 100 according to the first embodiment, the connection process is performed as illustrated in FIG. 2C. In the connection process, the chip 30 is connected on the conductive member 10 via the solder layer 20. In the connection process, for example, the chip 30 is connected on the conductive member 10 via the solder layer 20 by reflow.

Then, according to the method for manufacturing the semiconductor device 100 according to the first embodiment, the sealing process is performed as illustrated in FIG. 2D. In the sealing process, the solder layer 20, the chip 30, the coating film 40, and the insulating part 50 are sealed with the sealing resin 60. In the sealing process, for example, the sealing resin 60 is formed by coating a material including a thermosetting resin on the conductive member 10 and on the laminate of the solder layer 20, the chip 30, the coating film 40, and the insulating part 50 and by curing the thermosetting resin by heating.

Thus, the semiconductor device 100 according to the first embodiment can be manufactured by performing the preparation process, the dicing process, the connection process, and the sealing process described above.

### Second Embodiment

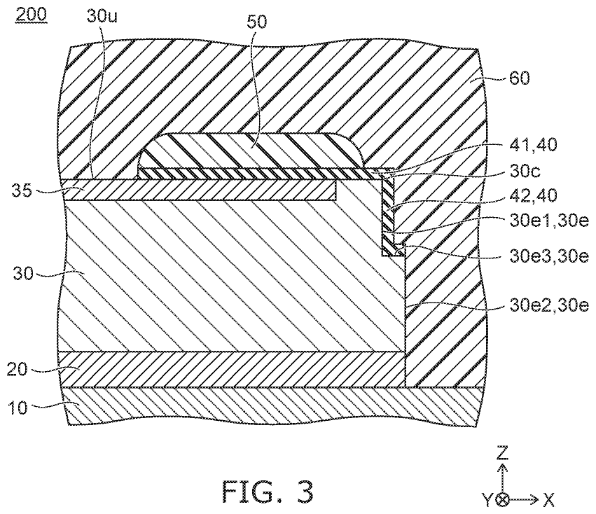

FIG. 3 is a cross-sectional view illustrating a semiconductor device according to a second embodiment.

In the semiconductor device 200 according to the second embodiment as illustrated in FIG. 3, the coating film 40 further includes a second covering part 42 in addition to the first covering part 41. Otherwise, the semiconductor device 200 is substantially the same as the semiconductor device 100 according to the first embodiment.

The second covering part 42 covers the side surface 30eof the chip 30. More specifically, the second covering part 42 covers a portion of the side surface 30e of the chip 30. The second covering part 42 maycover the entire side surface 30e of the chip 30. The second covering part 42 is connected with the first covering part 41.

In the example, the side surface 30e of the chip 30 includes a first side surface 30e1 and a second side surface 30e2.

The first side surface 30e1 is connected with the upper surface 30u of the chip 30. The second side surface 30e2 is positioned below the first side surface 30e1. The second side surface 30e2 is positioned further outward than the first side surface 30e1. That is, a step portion 30e3 is formed between the first side surface 30e1 and the second side surface 30e2. The step portion 30e3 connects the first side surface 30e1 and the second side surface 30e2. In the example, the second covering part 42 covers the first side surface 30e1 and the step portion 30e3. In the example, the second covering part 42 does not cover the second side surface 30e2.

Effects of the semiconductor device 200 according to the second embodiment will now be described.

In the semiconductor device 200 according to the second embodiment, similarly to the semiconductor device 100 according to the first embodiment, the expansion of the chip 30 can be suppressed because the outer perimeter edge 30c of the upper surface 30u of the chip 30 is covered with the coating film 40 (the first covering part 41). Cracks in the upper surface 30u of the chip 30 can be suppressed thereby, and short defects can be suppressed even when lead ions are generated. Accordingly, the reliability of the semiconductor device can be increased.

In the semiconductor device 200 according to the second embodiment, the expansion of the chip 30 can be further suppressed because the side surface 30e of the chip 30 is covered with the coating film 40 (the second covering part 42). Cracks in the chip 30 can be further suppressed thereby, and short defects can be further suppressed even when lead ions are generated. Accordingly, the reliability of the semiconductor device can be further increased.

A method for manufacturing the semiconductor device 200 according to the second embodiment will now be described.

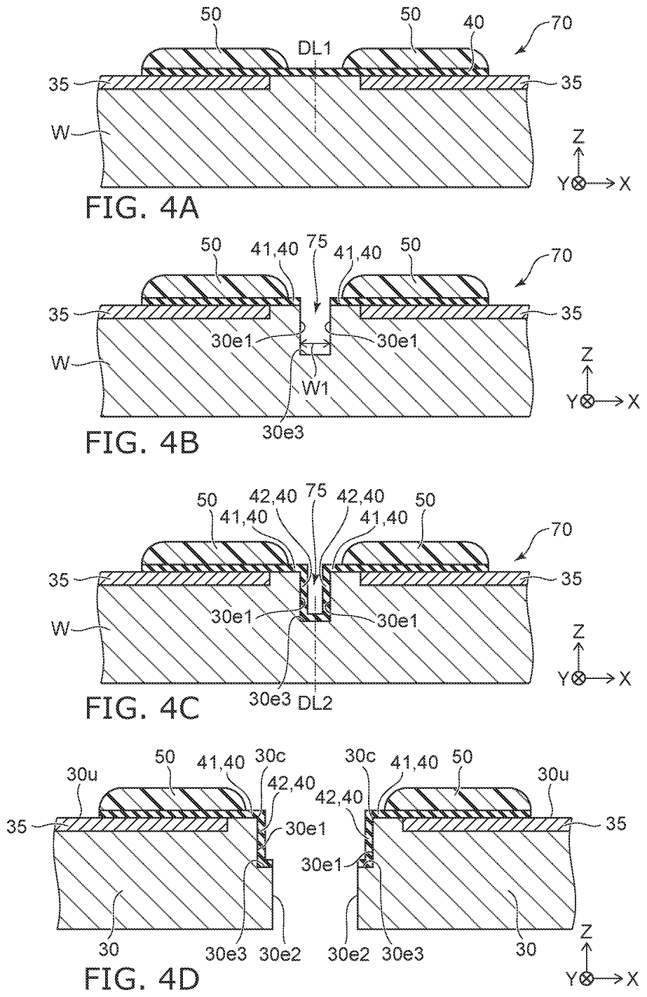

FIGS. 4A to 4D are cross-sectional views illustrating an example of the method for manufacturing the semiconductor device according to the second embodiment.

The method for manufacturing the semiconductor device 200 according to the second embodiment is substantially the same as the method for manufacturing the semiconductor device 100 according to the first embodiment except for performing a first dicing process (FIGS. 4A and 4B), a film formation process (FIG. 4C), and a second dicing process (FIGS. 4C and 4D) instead of the dicing process (FIGS. 2A and 2B).

FIGS. 4A to 4D illustrate the first dicing process, the film formation process, and the second dicing process. The preparation process, the connection process, and the sealing process are respectively similar to the preparation process (FIG. 2A), the connection process (FIG. 2C), and the sealing process (FIG. 2D) according to the method for manufacturing the semiconductor device 100 according to the first embodiment described above; and a description is therefore omitted.

According to the method for manufacturing the semiconductor device 200 according to the second embodiment, the first dicing process is performed after the preparation process as illustrated in FIGS. 4A and 4B. In the first dicing process, the stacked body 70 is diced partway at the position at which the coating film 40 is located. In the first dicing process, the stacked body 70 is diced along a dicing line DL1. At this time, the dicing is performed to form a trench 75 having a width W1 at the cutting location. The first side surface 30e1 corresponding to the side surface of the trench 75 and the step portion 30e3 corresponding to the bottom surface of the trench 75 are formed thereby. The dicing may be performed using a blade or may be performed using a laser.

Then, according to the method for manufacturing the semiconductor device 200 according to the second embodiment, the film formation process is performed as illustrated in FIG. 4C. In the film formation process, the coating film 40 (the second covering part 42) is formed at the first side surface 30e1. For example, the second covering part 42 is formed by CVD using TEOS. In the film formation process, for example, the coating film 40 (the second covering part 42) is formed at the step portion 30e3 in addition to the first side surface 30e1.

Then, according to the method for manufacturing the semiconductor device 200 according to the second embodiment, the second dicing process is performed as illustrated in FIGS. 4C and 4D. In the second dicing process, the stacked body 70 is diced to the lower end at the position of the trench 75 formed in the first dicing process. In the second dicing process, the stacked body 70 is diced along a dicing line DL2. The second side surface 30e2 is formed thereby. The dicing may be performed using a blade or may be performed using a laser.

By the first dicing process, the film formation process, and the second dicing process described above, the chip 30 is obtained in which the coating film 40 (the first covering part 41) and the insulating part 50 are stacked and the coating film 40 (the second covering part 42) is formed at the first side surface 30e1 and the step portion 30e3.

Then, the semiconductor device 200 according to the second embodiment can be manufactured by performing the connection process and the sealing process by using the chip 30 obtained in the second dicing process. Third embodiment

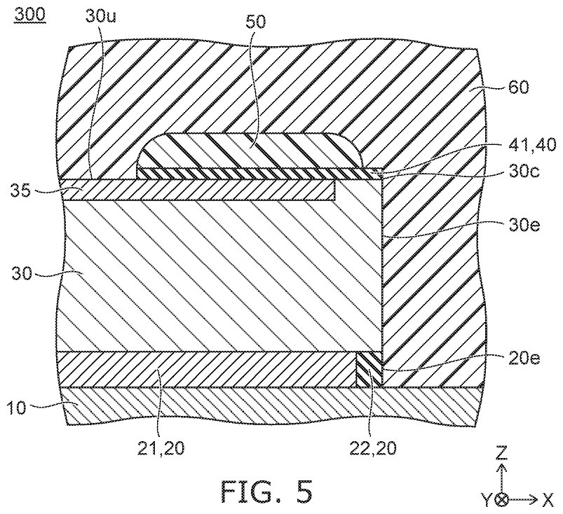

FIG. 5 is a cross-sectional view illustrating a semiconductor device according to a third embodiment.

In the semiconductor device 300 according to the third embodiment, the solder layer 20 includes a first solder part 21 and a second solder part 22 as illustrated in FIG. 5. Otherwise, the semiconductor device 300 is substantially the same as the semiconductor device 100 according to the first embodiment.

The first solder part 21 is a part of the solder layer 20 positioned at the center vicinity. The second solder part 22 is a part of the solder layer 20 positioned at the outer perimeter. The second solder part 22 is positioned outward of the first solder part 21. The second solder part 22 includes a side surface 20e of the solder layer 20. The second solder part 22 located outward of the first solder part 21 over the entire perimeter of the solder layer 20.

The first solder part 21 includes lead. For example, the first solder part 21 includes lead as a major component. The second solder part 22 includes lead oxide. For example, the second solder part 22 includes lead oxide as a major component. The second solder part 22 includes, for example, at least one of Pb₂O₃ or Pb₃O₄.

Effects of the semiconductor device 300 according to the third embodiment will now be described.

In the semiconductor device 300 according to the third embodiment, similarly to the semiconductor device 100 according to the first embodiment, the expansion of the chip 30 can be suppressed because the outer perimeter edge 30c of the upper surface 30u of the chip 30 is covered with the coating film 40 (the first covering part 41). Cracks in the upper surface 30u of the chip 30 can be suppressed thereby, and short defects can be suppressed even when lead ions are generated. Accordingly, the reliability of the semiconductor device can be increased.

In the semiconductor device 300 according to the third embodiment, the generation of lead ions can be suppressed by providing the second solder part 22 that includes lead oxide at the outer perimeter of the solder layer 20. Short defects can be further suppressed thereby. Accordingly, the reliability of the semiconductor device can be further increased.

A method for manufacturing the semiconductor device 300 according to the third embodiment will now be described.

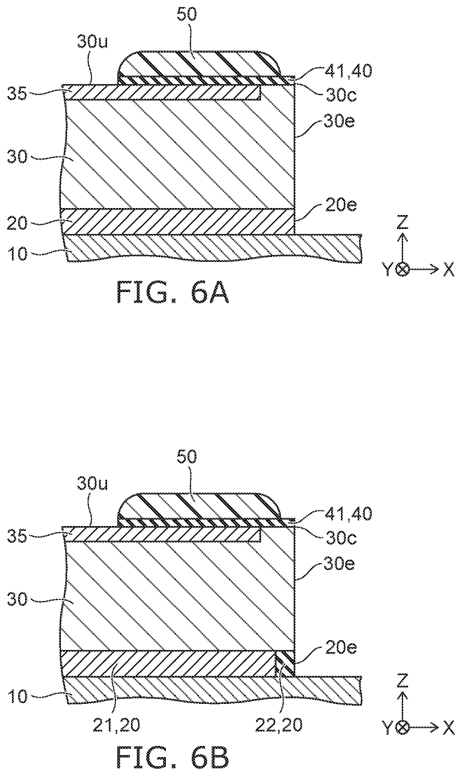

FIGS. 6A and 6B are cross-sectional views illustrating an example of the method for manufacturing the semiconductor device according to the third embodiment.

The method for manufacturing the semiconductor device 300 according to the third embodiment is substantially the same as the method for manufacturing the semiconductor device 100 according to the first embodiment, except for performing an oxidation process (FIGS. 6A and 6B) after the connection process and before the sealing process.

FIGS. 6A and 6B illustrate the oxidation process. The preparation process, the dicing process, the connection process, and the sealing process are respectively similar to the preparation process (FIG. 2A), the dicing process (FIGS. 2A and 2B), the connection process (FIG. 2C), and the sealing process (FIG. 2D) according to the method for manufacturing the semiconductor device 100 according to the first embodiment described above; and a description is therefore omitted.

According to the method for manufacturing the semiconductor device 300 according to the third embodiment, the oxidation process is performed after the preparation process, the dicing process, and the connection process as illustrated in FIGS. 6A and 6B. In the oxidation process, the solder layer 20 is oxidized from the side surface 20e. Accordingly, in the solder layer 20, the second solder part 22 that includes lead oxide can be formed outward of the first solder part 21 that includes lead. The upper surface 30u of the chip 30 is not oxidized when oxidizing the solder layer 20 because a gold film formed by gold plating or the like is on the upper surface 30u of the chip 30.

For example, the solder layer 20 is oxidized by heating in an oxygen atmosphere. It is sufficient for the oxygen atmosphere to include oxygen; and the oxygen atmosphere may include an inert gas. For example, it is favorable for the heating temperature to be not more than 200° C.

For example, the solder layer 20 maybe oxidized by blowing gas including oxygen onto the side surface 20e of the solder layer 20 while heating. It is sufficient for the gas that is blown to include oxygen; and the gas may include an inert gas. For example, it is favorable for the heating temperature to be not more than 200° C.

A laminate is obtained by the oxidation process described above in which the chip 30 is connected on the conductive member 10 via the solder layer 20 in which the second solder part 22 that includes lead oxide is formed outward of the first solder part 21 that includes lead.

Then, the semiconductor device 300 according to the third embodiment can be manufactured by performing the sealing process by using the laminate obtained in the oxidation process.

### Fourth Embodiment

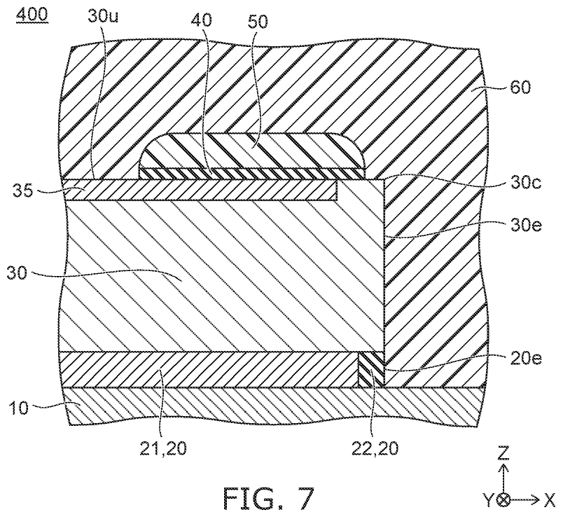

FIG. 7 is a cross-sectional view illustrating a semiconductor device according to a fourth embodiment.

In the semiconductor device 400 according to the fourth embodiment as illustrated in FIG. 7, the coating film 40 (the first covering part 41) does not cover the outer perimeter edge 30c of the upper surface 30u of the chip 30. Otherwise, the semiconductor device 400 is substantially the same as the semiconductor device 300 according to the third embodiment.

In the semiconductor device 400 according to the fourth embodiment, similarly to the semiconductor device 300 according to the third embodiment, the solder layer 20 includes the first solder part 21 and the second solder part 22. The first solder part 21 includes lead. The second solder part 22 includes lead oxide.

Effects of the semiconductor device 400 according to the fourth embodiment will now be described.

In the semiconductor device 400 according to the fourth embodiment, the generation of lead ions can be suppressed by providing the second solder part 22 that includes lead oxide at the outer perimeter of the solder layer 20. Short defects can be suppressed thereby. Accordingly, the reliability of the semiconductor device can be increased.

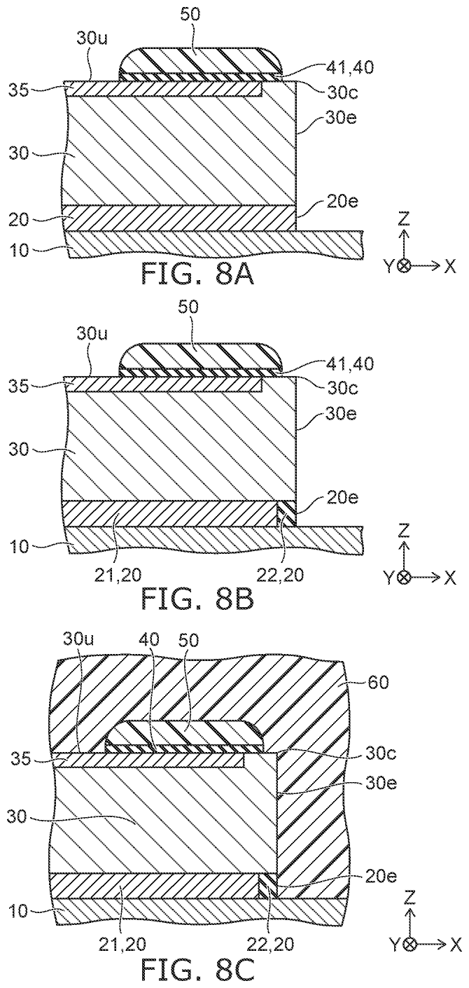

FIGS. 8A to 8C are cross-sectional views illustrating an example of the method for manufacturing the semiconductor device according to the fourth embodiment.

As illustrated in FIGS. 8A to 8C, the method for manufacturing the semiconductor device 400 according to the fourth embodiment includes the connection process, the oxidation process, and the sealing process.

According to the method for manufacturing the semiconductor device 400 according to the fourth embodiment, first, the connection process is performed as illustrated in FIG. 8A. In the connection process, the chip 30 is connected on the conductive member 10 via the solder layer 20 that includes lead. The connection process is similar to the connection process of the method for manufacturing the semiconductor device 100 according to the first embodiment (FIG. 2C); and a description is therefore omitted.

In the example, the chip 30 in which the coating film 40 and the insulating part 50 are stacked is connected on the conductive member 10. The chip 30 in which the coating film 40 and the insulating part 50 are stacked is obtained by performing the preparation process (FIG. 2A) and the dicing process (FIGS. 2A and 2B) according to the method for manufacturing the semiconductor device 100 according to the first embodiment described above. The chip 30 in which the outer perimeter edge 30c of the upper surface 30u of the chip 30 is not covered with the coating film 40 (the first covering part 41) is obtained by performing the dicing of the dicing process after removing the coating film 40 at the position overlapping the dicing line DL.

Then, according to the method for manufacturing the semiconductor device 400 according to the fourth embodiment, an oxidation process is performed as illustrated in FIGS. 8A and 8B. In the oxidation process, the solder layer 20 is oxidized from the side surface 20e. Accordingly, in the solder layer 20, the second solder part 22 that includes lead oxide can be formed outward of the first solder part 21 that includes lead. The oxidation process is similar to the oxidation process (FIGS. 6A and 6B) according to the method for manufacturing the semiconductor device 300 according to the third embodiment; and a description is therefore omitted.

Then, according to the method for manufacturing the semiconductor device 400 according to the fourth embodiment, a sealing process is performed as illustrated in FIG. 8C. In the sealing process, the solder layer 20 and the chip 30 are sealed with the sealing resin 60. In the example, the solder layer 20, the chip 30, the coating film 40, and the insulating part 50 are sealed with the sealing resin 60. The sealing process is similar to the sealing process (FIG. 2D) according to the method for manufacturing the semiconductor device 100 according to the first embodiment; and a description is therefore omitted.

Thus, the semiconductor device 400 according to the fourth embodiment can be manufactured by performing the connection process, the oxidation process, and the sealing process described above.

Embodiments may include the following configurations.

### Configuration 1

A semiconductor device, comprising:
a conductive member;
a solder layer located on the conductive member;
a chip located on the solder layer;
a coating film located on the chip, the coating film being insulative, the coating film including a first covering part, the first covering part covering an outer perimeter edge of an upper surface of the chip;
an insulating part located on the coating film; and
a sealing resin sealing the solder layer, the chip, the coating film, and the insulating part.

### Configuration 2

The device according to configuration 1, wherein
the coating film further includes a second covering part covering a side surface of the chip.

### Configuration 3

The device according to configuration 2, wherein
the side surface of the chip includes:
   a first side surface connected with the upper surface of the chip;
   a second side surface positioned below the first side surface and further outward than the first side surface; and
   a step portion connecting the first and second side surfaces, and
the second covering part covers the first side surface.

### Configuration 4

The device according to any one of configurations 1 to 3, wherein
the coating film includes at least one of silicon nitride, silicon oxide, or silicon oxynitride.

### Configuration 5

The device according to any one of configurations 1 to 4, wherein
the solder layer includes:
   a first solder part; and
   a second solder part positioned outward of the first solder part, the second solder part including a side surface of the solder layer,
the first solder part includes lead, and
the second solder part includes lead oxide.

### Configuration 6

The device according to configuration 5, wherein
the second solder part includes at least one of Pb₂O₃ or Pb₃O₄.

### Configuration 7

A method for manufacturing a semiconductor device, the method comprising:
a preparation process of preparing a stacked body in which a coating film is formed on a wafer, and an insulating part is formed on the coating film;
a dicing process of obtaining a chip by dicing the stacked body at a position at which the coating film is located, the coating film and the insulating part being stacked in the chip;
a connection process of connecting the chip on a conductive member via a solder layer; and
a sealing process of sealing the solder layer, the chip, the coating film, and the insulating part with a sealing resin.

### Configuration 8

The method for manufacturing the device according to configuration 7, further comprising:
an oxidation process of forming a second solder part outward of a first solder part by oxidizing the solder layer from a side surface,
the first solder part including lead,
the second solder part including lead oxide.

### Configuration 9

A semiconductor device, comprising:
a conductive member;
a solder layer located on the conductive member, the solder layer including a first solder part and a second solder part, the second solder part being positioned outward of the first solder part, the second solder part including a side surface;
a chip located on the solder layer; and
a sealing resin sealing the solder layer and the chip,
the first solder part including lead,
the second solder part including lead oxide.

### Configuration 10

A method for manufacturing a semiconductor device, the method comprising:
a connection process of connecting a chip on a conductive member via a solder layer, the solder layer including lead;
an oxidation process of forming a second solder part outward of a first solder part by oxidizing the solder layer from a side surface, the first solder part including lead, the second solder part including lead oxide; and
a sealing process of sealing the solder layer and the chip with a sealing resin.

Thus, according to embodiments of the invention, a semiconductor device and a method for manufacturing a semiconductor device are provided in which the reliability can be increased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

What is claimed is:

1. A semiconductor device, comprising:
a conductive member;
a solder layer located on the conductive member;
a chip located on the solder layer;
a coating film located on the chip, the coating film being insulative, the coating film including a first covering part, the first covering part covering an outer perimeter edge of an upper surface of the chip;
an insulating part located on the coating film; and
a sealing resin sealing the solder layer, the chip, the coating film, and the insulating part.

2. The device according to claim 1, wherein
the coating film further includes a second covering part covering a side surface of the chip.

3. The device according to claim 2, wherein
the side surface of the chip includes:
a first side surface connected with the upper surface of the chip;
a second side surface positioned below the first side surface and further outward than the first side surface; and
a step portion connecting the first and second side surfaces, and
the second covering part covers the first side surface.

4. The device according to claim 1, wherein
the coating film includes at least one of silicon nitride, silicon oxide, or silicon oxynitride.

5. The device according to claim 1, wherein
the solder layer includes:
a first solder part; and
a second solder part positioned outward of the first solder part, the second solder part including a side surface of the solder layer,
the first solder part includes lead, and
the second solder part includes lead oxide.

6. The device according to claim 5, wherein the second solder part includes at least one of Pb₂O₃ or Pb₃O₄.

7. A method for manufacturing a semiconductor device, the method comprising:
a preparation process of preparing a stacked body in which a coating film is formed on a wafer, and an insulating part is formed on the coating film;
a dicing process of obtaining a chip by dicing the stacked body at a position at which the coating film is located, the coating film and the insulating part being stacked in the chip;
a connection process of connecting the chip on a conductive member via a solder layer; and
a sealing process of sealing the solder layer, the chip, the coating film, and the insulating part with a sealing resin.

8. The method for manufacturing the device according to claim 7, wherein
the dicing process comprises a first step, a second step, and a third step,
in the first step, the stacked body is diced partway at a position at which the coating film is located to form a trench,
in the second step, a covering part is formed at a side surface of the trench, the covering part including same material as the coating film, and
in the third step, the stacked body is diced to a lower end at the position of the trench to obtain the chip.

9. The method for manufacturing the device according to claim 7, further comprising:
an oxidation process of forming a second solder part outward of a first solder part by oxidizing the solder layer from a side surface,
the first solder part including lead,
the second solder part including lead oxide.

10. A semiconductor device, comprising:
a conductive member;
a solder layer located on the conductive member, the solder layer including a first solder part and a second solder part, the second solder part being positioned outward of the first solder part, the second solder part including a side surface;
a chip located on the solder layer; and
a sealing resin sealing the solder layer and the chip,
the first solder part including lead,
the second solder part including lead oxide.
